(19) United States
(12) Patent Application Publication
(10) Pub. No.: US 2010/0246629 A1
(43) Pub. Date: Sep. 30, 2010

(54) MULTIPLE-WAVELENGTH LASER DEVICE

(75) Inventors: Takuya Fujii, Kanagawa (JP); Shoichi Ogita, Kanagawa (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SUMITOMO ELECTRIC DEVICE INNOVATIONS, INC., Kanagawa (JP)

(21) Appl. No.: 12/730,786

(22) Filed: Mar. 24, 2010

(30) Foreign Application Priority Data
Mar. 25, 2009 (JP) 2009-073579

(51) Int. Cl. H01S 5/026

(52) U.S. Cl. 372/50.121

(57) ABSTRACT

A multiple-wavelength laser device includes a first semiconductor laser chip having two modulable unit laser portions, outputs of the unit laser portions being optically coupled to a single output optical axis; a second semiconductor laser chip having two or less than two modulable unit laser portions, outputs of the unit laser portions being optically coupled to a single output optical axis; an optical coupler that combines the output optical axes of the first and the second semiconductor laser chips; and a plurality of drive current pathways or a plurality of signal transmission pathways that are coupled to each of the unit laser portions of the first and the second semiconductor laser chips with a connection conductor.

### CROSS-REFERENCE TO RELATED APPLICATION

This application is based upon and claims the benefit of priority of the prior Japanese Patent Application No. 2009-073579, filed on Mar. 25, 2009, the entire contents of which are incorporated herein by reference.

### BACKGROUND

(i) Technical Field

The present invention relates to a multiple-wavelength laser device having a plurality of semiconductor laser chips.

(ii) Related Art

An optical communication system using an optical fiber is being built according to speeding up of information communication. The optical communication system may use multiple-wavelength transmission method. Japanese Patent Application Publication No. 11-54842 (hereinafter referred to as Document 1) discloses a laser device having a plurality of semiconductor laser chips.

With the art of Document 1, there are many wires for providing electrical power or signal. This results in greater density of the wires. It is possible to produce many semiconductor laser chips from a wafer when the semiconductor laser chips are located on a small area. Therefore, an interval between unit laser portions is reduced. This results in greater density of the wires. In this case, freedom degree of wire track design is reduced. Therefore, there is a problem that modulation property may be degraded because of interference of high frequency wave signal.

### SUMMARY

It is an object of the present invention to provide a multiple-wavelength laser device having favorable modulation property.

According to an aspect of the present invention, there is provided a multiple-wavelength laser device including: a first semiconductor laser chip having two modulable unit laser portions, outputs of the unit laser portions being optically coupled to a single output optical axis; a second semiconductor laser chip having two or less than two modulable unit laser portions, outputs of the unit laser portions being optically coupled to a single output optical axis; an optical coupler that combines the output optical axes of the first and the second semiconductor laser chips; and a plurality of drive current pathways or a plurality of signal transmission pathways that are coupled to each of the unit laser portions of the first and the second semiconductor laser chips with a connection conductor.

### BRIEF DESCRIPTION OF THE DRAWINGS

FIG. 1A illustrates a schematic plane view of a semiconductor laser chip in accordance with a comparative embodiment;

FIG. 1B illustrates an arrangement of bonding wires connecting a semiconductor laser chip and a printed circuit substrate;

FIG. 2 illustrates a schematic view of a main part of a multiple-wavelength laser device in accordance with a first embodiment;

FIG. 3 illustrates a plane view of a multiple-wavelength laser device;

FIG. 4 illustrates a schematic plane view of a multiple-wavelength laser device in accordance with a second embodiment; and

FIG. 5 illustrates a schematic plane view of a multiple-wavelength laser device in accordance with a third embodiment.

### DETAILED DESCRIPTION

A description will be given of a multiple-wavelength laser device in accordance with a comparative embodiment in order to state a problem solved in the following embodiments.

### Comparative Embodiment

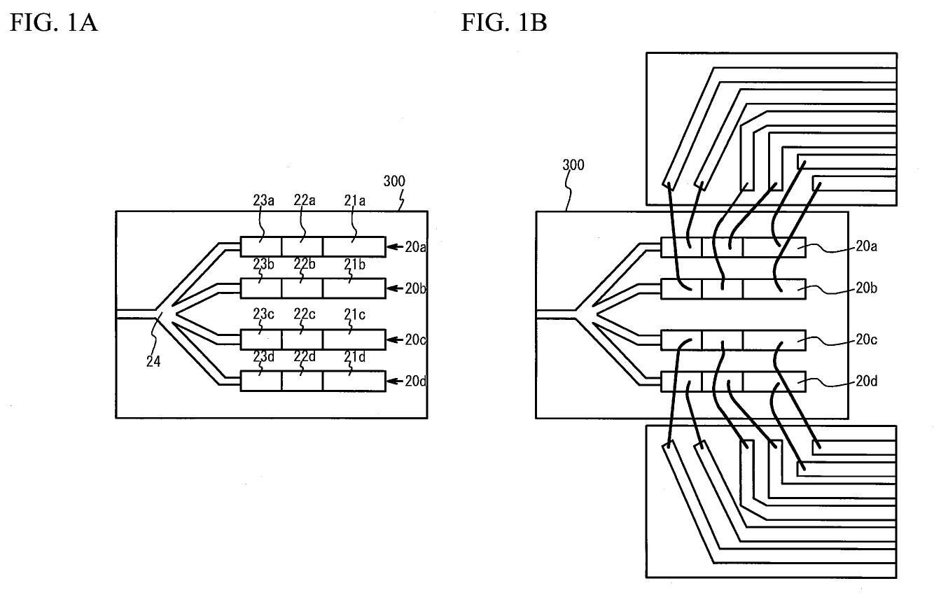

FIG. 1A illustrates a schematic plane view of a semiconductor laser chip 300 in accordance with a comparative embodiment. As illustrated in FIG. 1A, the semiconductor laser chip 300 has four unit laser portions 20a to 20d arranged in order. The unit laser portions 20a to 20d are arranged in array so that longitudinal directions thereof are substantially in parallel with each other. The unit laser portions 20a to 20d have a structure in which optical modulators 22a to 22d and SOAs (Semiconductor Optical Amplifier) 23a to 23d are coupled to outputting ends of laser portions 21a to 21d in order.

Optical signals from the unit laser portions 20a to 20d transmit in an optical waveguide having an optical axis different from each other. The optical waveguides are coupled to an optical waveguide having a single output optical axis in an optical multiplexer 24. Thus, the optical signals from the unit laser portions 20a to 20d are multiplexed at the optical multiplexer 24 and are output outward.

The unit laser portions 20a to 20d, the optical waveguides, and the optical multiplexer 24 make the semiconductor laser chip 300. The semiconductor laser chip 300 can transmit data at 100 Gb/s at a maximum if the unit laser portions 20a to 20d can operate at 25 Gb/s.

FIG. 1B illustrates an arrangement of bonding wires connecting the semiconductor laser chip 300 and a printed circuit substrate. As illustrated in FIG. 1B, the bonding wires are dense even if the bonding wires are connected to the semiconductor laser chip 300 from both sides of the array, because the bonding wires are connected to the two unit laser portions from a single side. This results in reduction of freedom degree of track design of a connection conductor to be connected to an optical modulator. Therefore, favorable modulation property may not be obtained. And, wire density causes reduction of yield ratio in a manufacturing process.

A length of a bonding wire connected to the optical modulator 22a and 22d may be at a minimum, because the optical modulators 22a and 22d are arranged outside of the array. However, a bonding wire connected to the optical modulators 22b and 22c is longer than the bonding wire connected to the optical modulators 22a and 22d, because it is necessary to connect the bonding wire and the optical modulators 22b and 22c across the optical modulators 22a and 22d. In this case, modulation property of the optical modulators 22b and 22c may be degraded. And, circuit designation may be complicated if each optical modulator having different length operates at the same property.

The four unit laser portions generate heat when operating in the semiconductor laser chip 300. In this case, temperature relation between the unit laser portions 20b and 20c and the unit laser portions 20a and 20d may be asymmetric. Therefore, operation property of each of the unit laser portions is different from each other.

### First Embodiment

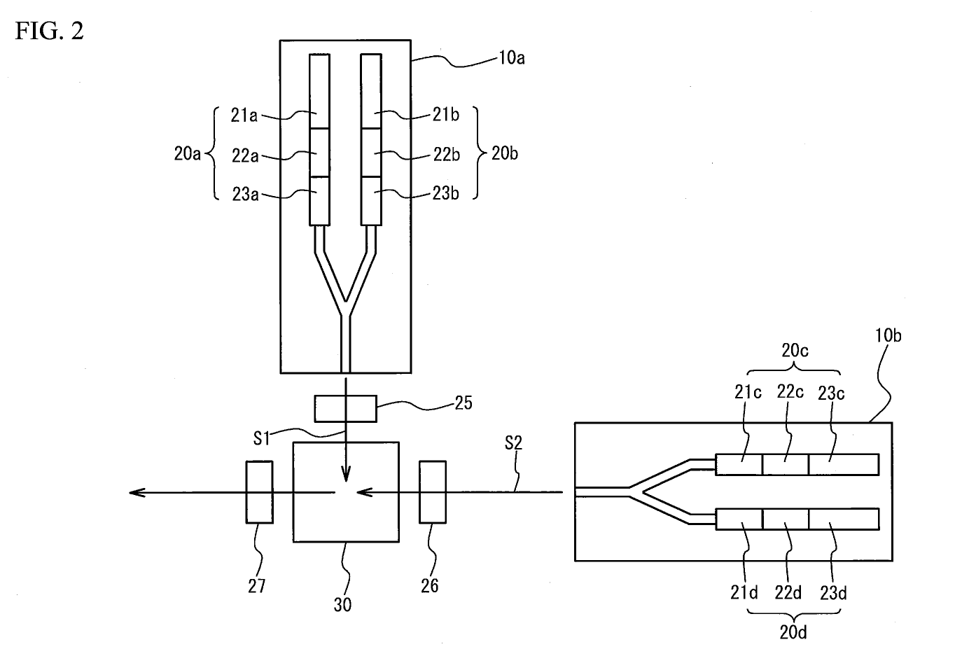

FIG. 2 illustrates a schematic view of a main part of a multiple-wavelength laser device 100 in accordance with a first embodiment. As illustrated in FIG. 2, the multiple-wavelength laser device 100 has a semiconductor laser chip 10a and a semiconductor laser chip 10b. The semiconductor laser chip 10a has unit laser portions 20a and 20b. Longitudinal directions of the unit laser portions 20a and 20b are substantially in parallel with each other. The semiconductor laser chip 10b has unit laser portions 20c and 20d. Longitudinal directions of the unit laser portions 20c and 20d are substantially in parallel with each other.

The unit laser portions 20a to 20d respectively have a structure in which the optical modulators 22a to 22d and the SOAs 23a to 23d are respectively connected to outputting ends of the laser portions 21a to 21d in order. In the unit laser portion 20a, an optical signal from the laser portion 21a is fed into the optical modulator 22a. The optical modulator 22a modulates the optical signal and provides a modulation signal into the SOA 23a. The SOA 23a amplifies the modulation signal and outputs the amplified modulation signal. In the unit laser portions 20b to 20d, modulation signals are output from the SOAs 23b to 23d with the same processes.

The modulation signals from the SOAs 23a and 23b are multiplexed at a wavelength multiplexer in an optical waveguide and are output as a modulation signal S1. The modulation signals from the SOAs 23c and 23d are multiplexed at a wavelength multiplexer in an optical waveguide and are output as a modulation signal S2. In the embodiment, an optical axis of the modulation signal S1 and an optical axis of the modulation signal S2 are at right angle with each other. The modulation signal S1 is fed into an optical coupler 30 through a lens 25. The modulation signal S2 is fed into the optical coupler 30 through a lens 26.

In the embodiment, a PBS (Polarization Beam Splitter) is used as the optical coupler 30. The modulation signals S1 and S2 are multiplexed at the optical coupler 30 and are output outside through a lens 27.

With the structure, the semiconductor laser chip 10a is separated away from the semiconductor laser chip 10b. In this case, bonding wire density is restrained. Therefore, flexibility of track design of the bonding wires connected to the optical modulators 22a to 22d is improved. Accordingly, favorable modulation property is obtained. And yield ratio in a manufacturing process may be improved if the wire density is restrained.

Multiplexing loss at the optical coupler 30 may be restrained because the optical coupler 30 is a polarization beam splitter.

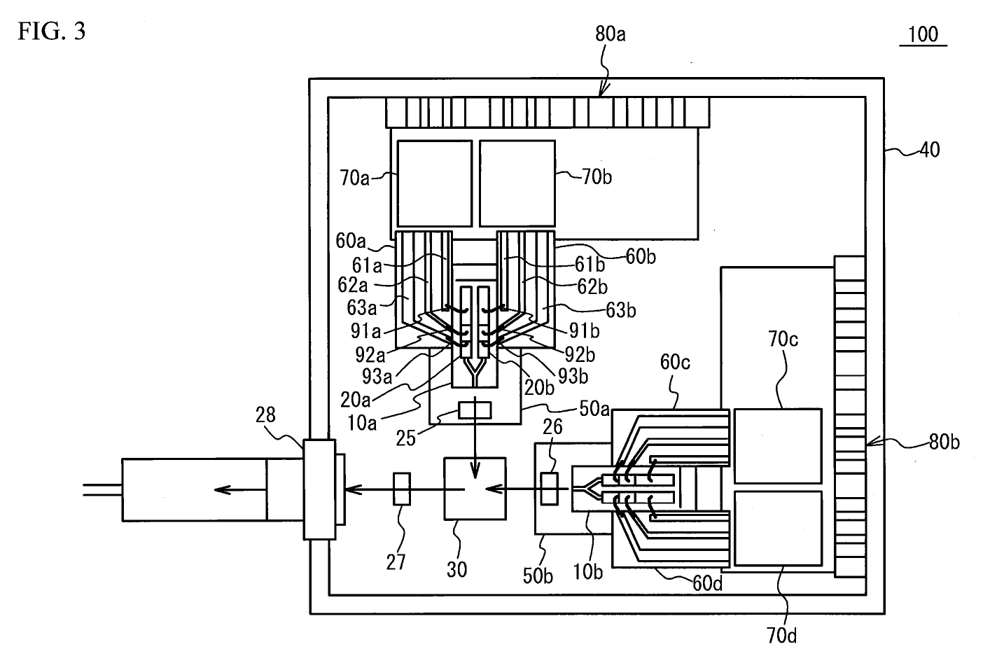

FIG. 3 illustrates a plane view of the multiple-wavelength laser device 100. As illustrated in FIG. 3, the multiple-wavelength laser device 100 has a structure in which a main part thereof illustrated in FIG. 2 is housed in a package 40. There are provided temperature control devices 50a and 50b, printed circuit substrates 60a to 60d, driver ICs 70a to 70d and external connection terminals 80a and 80b in the package 40. There is provided an optical connector 28 at a sidewall of the package 40.

The semiconductor laser chip 10a and the lens 25 are arranged on the temperature control device 50a. The semiconductor laser chip 10b and the lens 26 are arranged on the temperature control device 50b.

In the embodiment, an output optical axis of the unit laser portions 20a and 20b is different from that of the unit laser portions 20c and 20d. In this case, the unit laser portions 20a and 20b may be arranged away from the unit laser portions 20c and 20d. Therefore, the printed circuit substrates 60a to 60d can be respectively arranged adjacent to the unit laser portions 20a to 20d. In FIG. 3, reference numerals of each part of the unit laser portions 20a to 20d are omitted.

The printed circuit substrate 60a is arranged on the unit laser portion 20a side, compared to the temperature control device 50a. Metal wires 61a to 63a acting as drive current pathway or a signal transmission pathway are provided on the printed circuit substrate 60a. One end of the metal wire 61a is connected to the laser portion 21a with a bonding wire 91a. One end of the metal wire 62a is connected to the optical modulator 22a with a bonding wire 92a. The metal wire 63a is connected to the SOA 23a with a bonding wire 93a. The bonding wires 91a to 93a act as a connection conductor.

Another end of the metal wires 61a to 63a is connected to the driver IC 70a. Therefore, the laser portion 21a receives a laser driving current through the metal wire 61a. The optical modulator 22a receives a modulation signal through the metal wire 62a. The SOA 23a receives a SOA driving current through the metal wire 63a.

The printed circuit substrate 60b is arranged on the unit laser portion 20b side, compared to the temperature control device 50a. Therefore, the printed circuit substrate 60b is arranged in an opposite side of the unit laser portion 20a. The printed circuit substrate 60b has metal wires 61b to 63b. One end of the metal wire 61b is connected to the laser portion 21b with a bonding wire 91b. One end of the metal wire 62b is connected to the optical modulator 22b with a bonding wire 92b. The metal wire 63b is connected to the SOA 23b with a bonding wire 93b.

Another end of the metal wires 61b to 63b is connected to the driver IC 70b. Therefore, the laser portion 21b receives a laser driving current through the metal wire 61b. The optical modulator 22b receives a modulation signal through the metal wire 62b. The SOA 23b receives a SOA driving current through the metal wire 63b.

With the structure, a distance may be reduced to the minimum between each part of the unit laser portion 20a and the metal wires 61a to 63a and between each part of the unit laser portion 20b and the metal wires 61b to 63b. Therefore, degradation of modulation property may be restrained. And it is possible to design a structure in which a length of the bonding wire 92a connecting the optical modulator 22a and the metal wire 62a is the same as that of the bonding wire 92b connecting the optical modulator 22b and the metal wire 62b. In this case, the optical modulators 22a and 22b may operate at the same modulation property.

Similarly, the printed circuit substrate 60c is arranged on the unit laser portion 20c side, compared to the temperature control device 50b, and the printed circuit substrate 60d is arranged on the unit laser portion 20d side, compared to the temperature control device 50b. In this case, a distance may be reduced to the minimum between each part of the unit laser portion 20c and the metal wires of the printed circuit substrate 60c. And a distance may be reduced to the minimum between each part of the unit laser portion 20d and the metal wires of the printed circuit substrate 60d. Therefore, degradation of modulation property of the semiconductor laser chip 10b may be restrained. And it is possible to design a structure in which a length of a bonding wire connecting the optical modulator 22c and a metal wire is the same as that of a bonding wire connecting the optical modulator 22d and a metal wire. In this case, the optical modulators 22c and 22d may operate at the same modulation property. The SOA and the optical modulator may be arranged in order with respect to the unit laser portion.

The unit laser portions 20a and 20b are arranged symmetrically on the temperature control device 50a. Therefore, a temperature difference may be restrained between the unit laser portion 20a and the unit laser portion 20b. And, a temperature difference may be restrained between the unit laser portion 20c and unit laser portion 20d. Therefore, operation property difference between each unit laser portion may be restrained.

The optical coupler 30 multiplexes an optical signal from the semiconductor laser chip 10a and an optical signal from the semiconductor laser chip 10b. The optical coupler 30 outputs the multiplexed signal outward through the lens 26. From a view of restrain of polarized wave, the semiconductor laser chips 10a and 10b may be arranged by rotating with respect to the output optical axis thereof.

### Second Embodiment

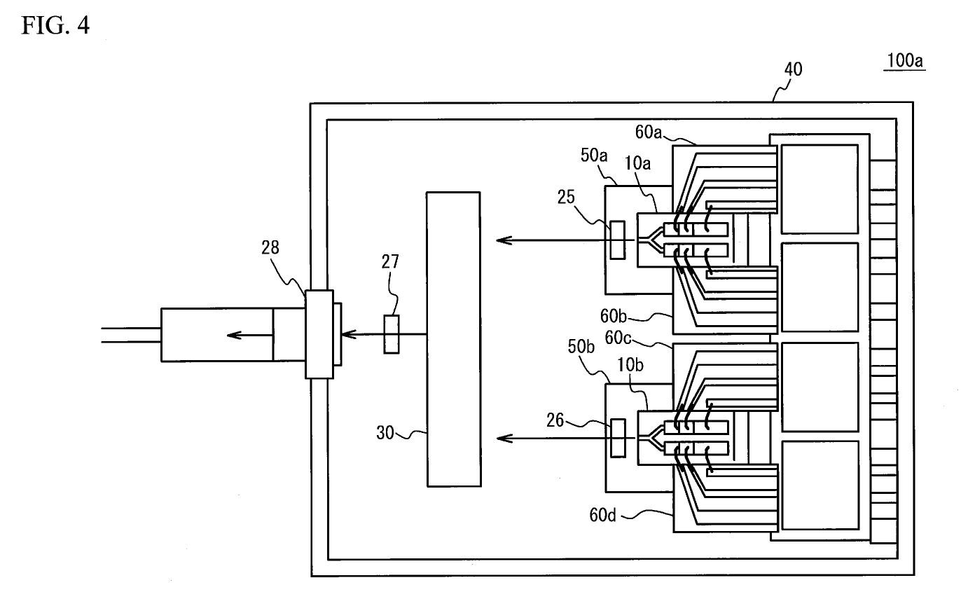

FIG. 4 illustrates a schematic plane view of a multiple-wavelength laser device 100a in accordance with a second embodiment. As illustrated in FIG. 4, the multiple-wavelength laser device 100a is different from the multiple-wavelength laser device 100 of FIG. 3 in a point that an optical axis of the semiconductor laser chip 10a is substantially in parallel with that of the semiconductor laser chip 10b. In the embodiment, a PLC (Planar Lightwave Circuit), a WDM (Wavelength Division Duplexing), and so on may be used as the optical coupler 30.

In the embodiment, the semiconductor laser chip 10a may be separated away from the semiconductor laser chip 10b, because the semiconductor laser chips 10a and 10b have two or less than two unit laser portions. Therefore, bonding wire density may be restrained. The printed circuit substrates may be arranged on both sides of the semiconductor laser chips 10a and 10b with respect to each of the unit laser portions. The length of the bonding wires connected to the optical modulators 22a to 22d may be reduced to the minimum, and may be the same.

### Third Embodiment

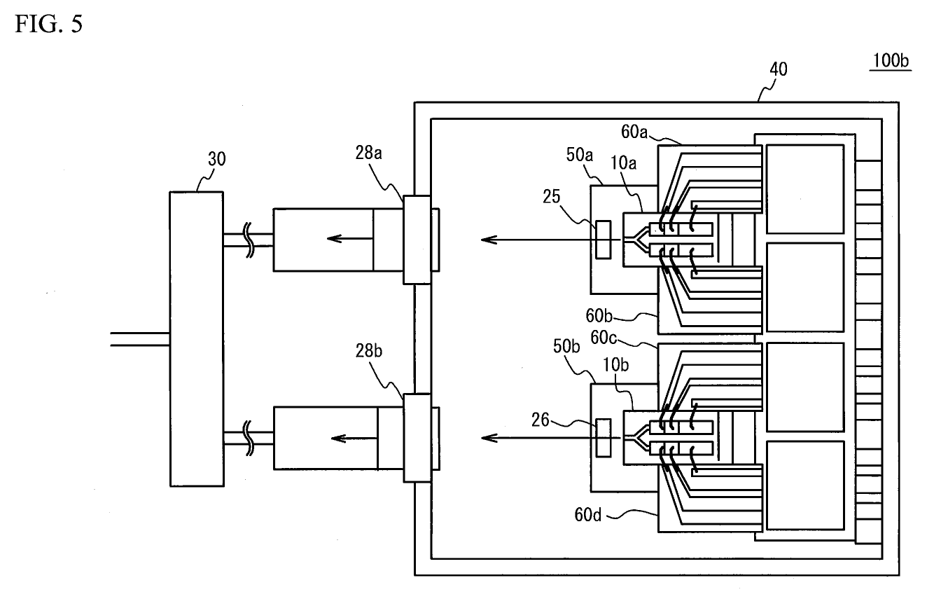

The optical coupler 30 may be provided outside of the package 40. FIG. 5 illustrates a schematic plane view of a multiple-wavelength laser device 100b in accordance with a third embodiment. As illustrated in FIG. 5, the multiple-wavelength laser device 100b is different from the multiple-wavelength laser device 100a of FIG. 4 in a point that the optical coupler 30 is provided outside of the package 40. In this case, the optical coupler 30 receives an output light of the semiconductor laser chip 10a through an optical connector 28a provided on a sidewall of the package 40. The optical coupler 30 receives an output light of the semiconductor laser chip 10b through an optical connector 28b on a sidewall of the package 40.

In the above-mentioned embodiments, two semiconductor laser chips having two unit laser portions are provided.

However, the structures are not limited. One of the semiconductor laser chips has only one unit laser portion.

The present invention is not limited to the specifically disclosed embodiments and variations but may include other embodiments and variations without departing from the scope of the present invention.

What is claimed is:

1. A multiple-wavelength laser device comprising:
a first semiconductor laser chip having two modulable unit laser portions, outputs of the unit laser portions being optically coupled to a single output optical axis;
a second semiconductor laser chip having two or less than two modulable unit laser portions, outputs of the unit laser portions being optically coupled to a single output optical axis;
an optical coupler that combines the output optical axes of the first and the second semiconductor laser chips; and
a plurality of drive current pathways or a plurality of signal transmission pathways that are coupled to each of the unit laser portions of the first and the second semiconductor laser chips with a connection conductor.

2. The multiple-wavelength laser device as claimed in claim 1, wherein the drive current pathway or the signal transmission pathway is provided on each sides of the first semiconductor laser chip and the second semiconductor laser chip.

3. The multiple-wavelength laser device as claimed in claim 1, wherein the first semiconductor laser chip is provided on a temperature control device and the second semiconductor laser chip is provided on another temperature control device.

4. The multiple-wavelength laser device as claimed in claim 1, wherein an output optical axis of the first semiconductor laser chip is at right angle with that of the second semiconductor laser chip.

5. The multiple-wavelength laser device as claimed in claim 1, wherein an output optical axis of the first semiconductor laser chip is in parallel with that of the second semiconductor laser chip.

6. The multiple-wavelength laser device as claimed in claim 1, wherein the first semiconductor laser chip, the second semiconductor laser chip and the optical coupler are arranged in a single package.

7. The multiple-wavelength laser device as claimed in claim 1, wherein each unit laser portion of the first and the second semiconductor laser chips has an optical modulator and a SOA region.

8. The multiple-wavelength laser device as claimed in claim 1, wherein the optical coupler is one of polarization beam splitter, a planar lightwave circuit, and a wavelength division duplexing coupler.

9. The multiple-wavelength laser device as claimed in claim 1 further comprising a driver IC that is coupled to one of the drive current pathway and the signal transmission pathway, and drives the first and the second semiconductor laser chips.

10. The multiple-wavelength laser device as claimed in claim 4, wherein a package including the first and the second semiconductor laser chips has a structure in which each side having external terminal is at right angle with each other.

11. The multiple-wavelength laser device as claimed in claim 1, wherein:
an output optical axis of the first semiconductor laser chip is at right angle with that of the second semiconductor laser chip; and
the first semiconductor laser chip, the second semiconductor laser chip and the optical coupler are arranged in a single package.

12. The multiple-wavelength laser device as claimed in claim 1, wherein:
an output optical axis of the first semiconductor laser chip is in parallel with that of the second semiconductor laser chip; and
the first semiconductor laser chip, the second semiconductor laser chip and the optical coupler are arranged in a single package.
